(19) United States
(12) Patent Application Publication
(10) Pub. No.: US 2024/0118216 A1
(43) Pub. Date: Apr. 11, 2024

(54) CHEMICAL TEST APPARATUS AND SUBSTRATE PROCESSING APPARATUS

(71) Applicant: SEMES CO., LTD., Cheonan-si (KR)

(72) Inventors: Sangwoo PARK, Cheonan-si (KR); Gi Hun CHOI, Cheonan-si (KR); Seong Hyeon KIM, Cheonan-si (KR); Seungtae YANG, Cheonan-si (KR)

(73) Assignee: SEMES CO., LTD., Cheonan-si (KR)

(21) Appl. No.: 18/376,429

(22) Filed: Oct. 3, 2023

(30) Foreign Application Priority Data
Oct. 5, 2022 (KR) 10-2022-0127299

(51) Int. Cl. G01N 21/85; H01L 21/67

(52) U.S. Cl. CPC G01N 21/8507; H01L 21/67051; G01N 2021/8528

(57) ABSTRACT

Provided is a chemical test apparatus for testing a chemical used to process a substrate, the chemical test apparatus including a first line providing an inlet through which the chemical is introduced, and a passage through which the chemical moves, a second line having an end and another end connected to two separate points of the first line, and providing a passage in which the chemical introduced into the first line is filled, a discharge line connected to a lower end of the first line, and a valve disposed between the first line and the discharge line at least below portions of the first line connected to the second line, to open or close a passage through which the chemical moves from the first line to the discharge line.

### CROSS-REFERENCE TO RELATED PATENT APPLICATION

This application claims the benefit of Korean Patent Application No. 10-2022-0127299, filed on Oct. 5, 2022, in the Korean Intellectual Property Office, the disclosure of which is incorporated herein in its entirety by reference.

### BACKGROUND OF THE INVENTION

### 1. Field of the Invention

The present invention relates to a semiconductor apparatus and, more particularly, to a chemical test apparatus and a substrate processing apparatus.

### 2. Description of the Related Art

Various processes such as photolithography, etching, ashing, ion implantation, deposition, and cleaning are performed on substrates to manufacture semiconductor devices, and various substrate processing apparatuses are used for such processes. Circuit patterns are getting finer and denser for higher performance of the semiconductor devices, and contaminants such as particulates, organic substances, and metals remaining on the surface of the substrates may exert a significant influence on the characteristics and a production yield of the semiconductor devices. As such, the cleaning process is required to remove various process materials and contaminants on the surface of the substrates, and the substrates may be cleaned in every unit process of the semiconductor manufacturing procedure.

To clean each substrate, chemical treatment, rinsing, and drying may be sequentially performed. Metals, organic substances, particulates, etc. remaining on the substrate are removed in the chemical treatment step, a chemical remaining on the substrate are removed using a rinsing solution such as deionized (DI) water in the rinsing step, and the substrate is dried using nitrogen gas or an organic solvent such as isopropyl alcohol (IPA) in the drying step.

In addition to the substrate cleaning process, a chemical is used to process the substrate in various processes. In general, for substrate processing, instead of using only a single chemical, one chemical may be used and then a process using another chemical may be followed. As such, to test a chemical supplied for each process, a contaminant test, a component test, or the like needs to be performed on the chemical. In addition, a test structure and test method capable of increasing convenience and reliability of the chemical test is required.

### SUMMARY OF THE INVENTION

The present invention provides a chemical test apparatus capable of increasing convenience and reliability a chemical test by performing the chemical test on a chemical without bubbles, and a substrate processing apparatus using the chemical test apparatus.

The present invention also provides a chemical test apparatus capable of increasing accuracy of measurement by preventing contamination of a chemical, and a substrate processing apparatus using the chemical test apparatus.

However, the above description is an example, and the scope of the present invention is not limited thereto.

According to an aspect of the present invention, there is provided a chemical test apparatus for testing a chemical used to process a substrate, the chemical test apparatus including a first line providing an inlet through which the chemical is introduced, and a passage through which the chemical moves, a second line having an end and another end connected to two separate points of the first line, and providing a passage in which the chemical introduced into the first line is filled, a discharge line connected to a lower end of the first line, and a valve disposed between the first line and the discharge line at least below portions of the first line connected to the second line, to open or close a passage through which the chemical moves from the first line to the discharge line.

The end of the second line may be connected to a lower one of the two separate points of the first line, and the other end of the second line may be connected to an upper one of the two separate points of the first line.

A photometer may irradiate light to the chemical to perform a test, and the second line may be provided as a target to which the light is irradiated.

When the valve is closed, the chemical introduced into the first line may be filled from the lower end of the first line and filled in at least a partial passage of the second line.

The chemical filled in the second line may include less bubbles than the chemical filled in the first line, and be provided as a target to which the light is irradiated.

The first line may extend in a Z-axis direction.

The first line may extend in a direction tilted at a certain angle with respect to a Z-axis direction.

A passage diameter of the second line may be less than or equal to a passage diameter of the first line.

A direction parallel to a cross-section of the second line, which has a length greater than a passage diameter of the second line, may be provided as a direction in which a light is irradiated.

A drain cup may be connected to the inlet of the first line and provide a receiver including an axis direction parallel to and spaced apart from at least an axis direction along which the first line extends.

The receiver may include a plane inclined or curved at a certain angle, and the chemical may be supplied onto the plane of the receiver.

The chemical test apparatus may further include a third line having an end and another end connected to two separate points respectively included in the first line and the discharge line, and providing a passage through which the chemical moves, and the end of the third line may be connected to a point of the discharge line below the valve, and the other end of the third line may be connected to a point of the first line above the other end of the second line.

When the chemical is fully filled in the second line, the chemical may move along the passage of the third line and be discharged through the discharge line.

A sensor for detecting whether the chemical is filled may be provided on the second line and/or on a point of the first line above the other end of the second line.

According to another aspect of the present invention, there is provided a substrate processing apparatus including a substrate supporter provided to support a substrate, a liquid ejector for ejecting a chemical used to process the substrate, and a chemical tester for testing the chemical used to process the substrate, wherein the chemical tester includes a first line providing an inlet through which the chemical is introduced, and a passage through which the chemical moves, a second line having an end and another end connected to two separate points of the first line, and providing a passage in which the chemical introduced into the first line is filled, a discharge line connected to a lower end of the first line, and a valve disposed between the first line and the discharge line at least below portions of the first line connected to the second line, to open or close a passage through which the chemical moves from the first line to the discharge line.

The substrate processing apparatus may further include a driver for moving the liquid ejector toward the chemical tester or the substrate supporter.

The substrate processing apparatus may further include a photometer for irradiating light to the second line of the chemical tester to test the chemical filled in the second line.

A drain cup may be connected to the inlet of the first line and provide a receiver including an axis direction parallel to and spaced apart from at least an axis direction along which the first line extends, the receiver may include a plane inclined or curved at a certain angle, and the driver may move the liquid ejector to a position vertically spaced apart from the receiver, to supply the chemical onto the plane of the receiver.

The chemical tester may further include a third line having an end and another end connected to two separate points respectively included in the first line and the discharge line, and providing a passage through which the chemical moves, the end of the third line may be connected to a point of the discharge line below the valve, and the other end of the third line may be connected to a point of the first line above the other end of the second line and, when the chemical is fully filled in the second line, the chemical may move along the passage of the third line and be discharged through the discharge line.

According to another aspect of the present invention, there is provided a chemical test apparatus for testing a chemical used to process a substrate, the chemical test apparatus including a first line providing an inlet through which the chemical is introduced, and a passage through which the chemical moves, a second line having an end and another end connected to two separate points of the first line, and providing a passage in which the chemical introduced into the first line is filled, a discharge line connected to a lower end of the first line, a third line having an end and another end connected to two separate points respectively included in the first line and the discharge line, and providing a passage through which the chemical moves, and a valve disposed between the first line and the discharge line at least below portions of the first line connected to the second line, to open or close a passage through which the chemical moves from the first line to the discharge line, wherein the end of the second line is connected to a lower one of the two separate points of the first line, and the other end of the second line is connected to an upper one of the two separate points of the first line, wherein the end of the third line is connected to a point of the discharge line below the valve, and the other end of the third line is connected to a point of the first line above the other end of the second line, wherein a drain cup is connected to the inlet of the first line and provides a receiver including an axis direction parallel to and spaced apart from at least an axis direction along which the first line extends, wherein the receiver includes a plane inclined or curved at a certain angle, wherein the chemical is supplied onto the plane of the receiver to flow along the plane of the receiver toward the inlet of the first line, wherein, when the valve is closed, the chemical introduced into the first line is filled from the lower end of the first line and filled in at least a partial passage of the second line, and wherein a photometer irradiates light to the chemical to perform a test, and the second line is provided as a target to which the light is irradiated.

### BRIEF DESCRIPTION OF THE DRAWINGS

The above and other features and advantages of the present invention will become more apparent by describing in detail embodiments thereof with reference to the attached drawings in which:

FIG. 1 is a plan view of substrate processing equipment according to an embodiment of the present invention;

FIG. 2 is a cross-sectional view of a substrate processing apparatus according to an embodiment of the present invention;

FIG. 3 is a cross-sectional view showing a chemical supply structure according to an embodiment of the present invention;

FIG. 4 is a schematic view of an existing chemical test apparatus;

FIG. 5 is a schematic view of a chemical test apparatus according to an embodiment of the present invention;

FIG. 6 is a schematic view of a chemical test apparatus according to an embodiment of the present invention when tilted;

FIG. 7 is a schematic view of a chemical test apparatus according to another embodiment of the present invention; and

FIG. 8 is a schematic view of a chemical test apparatus according to another embodiment of the present invention.

### DETAILED DESCRIPTION OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

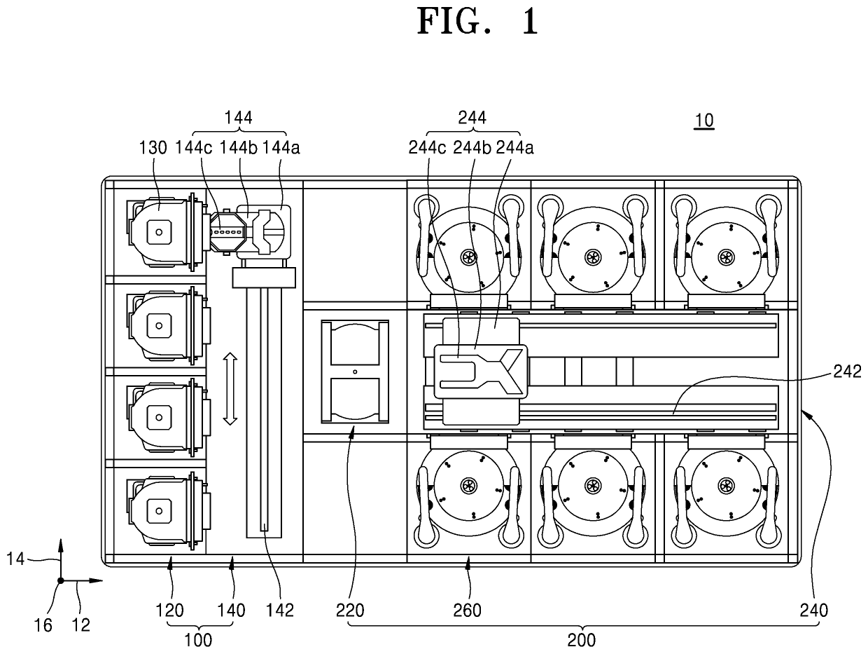

FIG. 1 is a plan view of substrate processing equipment 10 according to an embodiment of the present invention.

Referring to FIG. 1, the substrate processing equipment 10 includes an index module 100 and a process module 200. The index module 100 includes load ports 120 and a transfer frame 140. The load ports 120, the transfer frame 140, and the process module 200 may be sequentially arranged. Herein, a direction in which the load ports 120, the transfer frame 140, and the process module 200 are arranged is referred to as a first direction 12 (or an X-axis direction), a direction perpendicular to the first direction 12 when viewed from above is referred to as a second direction 14 (or a Y-axis direction), and a direction perpendicular to a plane including the first and second directions 12 and 14 (i.e., an XY plane) is referred to as a third direction 16 (or a Z-axis direction).

Carriers 130 containing substrates W are seated on the load ports 120. A plurality of load ports 120 may be disposed along the second direction 14. The number of load ports 120 may increase or decrease depending on process efficiency of the process module 200, production efficiency, or the like. Each carrier 130 may use a front opening unified pod (FOUP) and include slots for holding a plurality of substrates W horizontally.

The process module 200 includes a buffer unit 220, a transfer chamber 240, and process chambers 260. The transfer chamber 240 may extend parallel to the first direction 12, and the process chambers 260 may be disposed at both sides of the transfer chamber 240 along a longitudinal direction. Although not shown in FIG. 1, some of the process chambers 260 may be stacked on one another. Meanwhile, the process chambers 260 may be disposed only at one side of the transfer chamber 240.

The buffer unit 220 is disposed between the transfer frame 140 and the transfer chamber 240 to provide a space where the substrates W stay before being transferred between the transfer frame 140 and the transfer chamber 240. The buffer unit 220 includes slots where the substrates W are disposed. The buffer unit 220 may be provided to be open or openable to the transfer frame 140 and the transfer chamber 240.

The transfer frame 140 may transfer the substrates W between the carriers 130 and the buffer unit 220. The transfer frame 140 is provided with an index rail 142 and an index robot 144. The index rail 142 may extend parallel to the second direction 14, and the index robot 144 may be mounted thereon to move along the second direction 14. The index robot 144 includes a base 144a, a body 144b, and an index arm 144c. The base 144a is mounted to be movable along the index rail 142. The body 144b is coupled to the base 144a and mounted to be rotatable and movable along the third direction 16 on the base 144a. The index arm 144c is coupled to the body 144b and provided to be movable toward or away from the body 144b. A plurality of index arms 144c may be provided and individually driven. Each index arm 144c may be used to transfer the substrate W from the carrier 130 to the process module 200, or from the process module 200 to the carrier 130.

The transfer chamber 240 transfers the substrates W between the buffer unit 220 and the process chambers 260 or between the process chambers 260. The transfer chamber 240 is provided with a guide rail 242 and a main robot 244. The guide rail 242 may extend parallel to the first direction 12, and the main robot 244 may be mounted thereon to move along the first direction 12. The main robot 244 includes a base 244a, a body 244b, and a main arm 244c. The base 244a is mounted to be movable along the guide rail 242. The body 244b is coupled to the base 244a and mounted to be rotatable and movable along the third direction 16 on the base 244a. The main arm 244c is coupled to the body 244b and provided to be movable toward or away from the body 244b. A plurality of main arms 244c may be provided and individually driven.

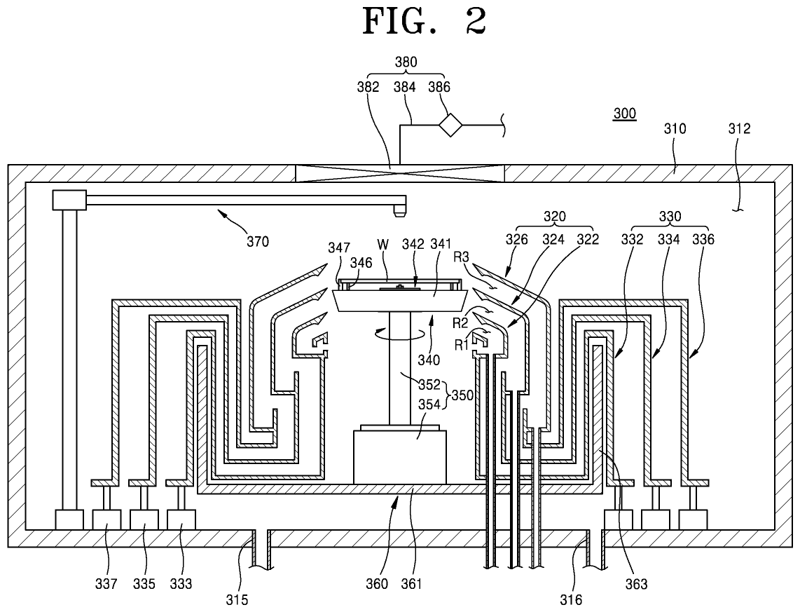

Each process chamber 260 is provided with a substrate processing apparatus 300 (see FIG. 2) for performing a process on the substrate W. The substrate processing apparatus 300 may have a different structure depending on the performed process. Meanwhile, the substrate processing apparatuses 300 in all process chambers 260 may have the same structure, or the substrate processing apparatuses 300 in the process chambers 260 belonging to the same group may have the same structure.

The substrate processing apparatus 300 (see FIG. 2) may perform a cleaning process by processing the substrate W with a liquid. The substrate processing apparatus 300 is described as a cleaning apparatus herein, but is not limited thereto, and it is noted that the substrate processing apparatus 300 is also applicable to heating apparatuses, etching apparatuses, photolithography apparatuses, etc. It is also noted that a chemical test apparatus 500 of the present invention is applicable to various substrate processing apparatuses such as cleaning apparatuses and heating apparatuses.

FIG. 2 is a cross-sectional view of a substrate processing apparatus 300 according to an embodiment of the present invention. The substrate processing apparatus 300 may be used as an apparatus for cleaning the substrate W.

Referring to FIG. 2, the substrate processing apparatus 300 includes a housing 310, a treatment vessel 320, lifts 330, a substrate supporter 340, a support driver 350, a base 360, a liquid ejector 370, and an airflow supplier 380.

The housing 310 provides an internal space 312. An opening (not shown) may be provided at a side of the housing 310 and used as a passage for the substrate W. A door (not shown) may be mounted on the opening to open or close the opening. When the substrate W is processed, the opening is closed to seal the internal space 312 of the housing 310. Exhaust ports 315 and 316 may be provided at a side of the housing 310 to expel an airflow formed in the housing 310 to the outside.

The treatment vessel 320 provides a space where the substrate W is processed. The treatment vessel 320 has an open top. The treatment vessel 320 includes a plurality of collection barrels 322, 324, and 326. Although three, e.g., first, second, and third, collection barrels 322, 324, and 326 are assumed in an embodiment of the present invention, the number of collection barrels may increase or decrease. The collection barrels 322, 324, and 326 are provided to be spaced apart from each other along a vertical direction (or the third direction 16). The collection barrels 322, 324, and 326 may be vertically stacked on one another. The first, second, and third collection barrels 322, 324, and 326 may collect different treatment liquids used in the process. The treatment vessel 320 provides one or more reception spaces R1, R2, and R3 formed in a vertical direction (or the third direction 16) to receive the treatment liquids after the substrate W is processed.

The first collection barrel 322 may be disposed to surround the substrate supporter 340, the second collection barrel 324 may be disposed to surround the first collection barrel 322, and the third collection barrel 326 may be disposed to surround the second collection barrel 324. The collection barrels 322, 324, and 326 are provided in a circular ring shape. A reception space R1 of the first collection barrel 322, a reception space R2 between the first and second collection barrels 322 and 324, and a reception space R3 between the second and third collection barrels 324 and 326 function as the reception spaces R1, R2, and R3 into which the treatment liquids flow. Collection pipes may extend downward from bottom surfaces of the collection barrels 322, 324, and 326 to discharge the treatment liquids introduced into the reception spaces R1, R2, and R3, respectively. The discharged treatment liquids may be reused through an external treatment liquid recycling system (not shown).

The lifts 330 are coupled to the collection barrels 322, 324, and 326 to lift the collection barrels 322, 324, and 326. A first lift 332 is connected to the first collection barrel 322, a second lift 334 is connected to the second collection barrel 324, and a third lift 336 is connected to the third collection barrel 326. The lifts 332, 334, and 336 may be connected to driving units 333, 335, and 337, respectively, to receive a driving force for vertical motion. The lifts 330 may control heights of the collection barrels 322, 324, and 326 to adjust sizes, heights, positions, or the like of the reception spaces R1, R2, and R3.

The substrate supporter 340 supports and rotates the substrate W in the internal space 312 of the housing 310. The substrate supporter 340 is disposed in an internal space of the treatment vessel 320. The substrate supporter 340 includes a rotating support plate 341 and a fixed support plate 342.

The rotating support plate 341 has a substantially circular upper edge when viewed from above. The rotating support plate 341 is positioned outside the fixed support plate 342. The rotating support plate 341 is rotated by the support driver 350. Support pins 346 and chuck pins 347 are provided on the rotating support plate 341. The fixed support plate 342 has a substantially circular upper edge when viewed from above. The fixed support plate 342 is positioned at the center of the substrate supporter 340.

The support driver 350 may rotate or lift the substrate supporter 340. The support driver 350 is connected to the rotating support plate 341 of the substrate supporter 340. The support driver 350 includes a driving shaft 352 and an actuator 354. The driving shaft 352 is rotated by the actuator 354 to rotate the rotating support plate 341. In addition, the driving shaft 352 may be moved or stretched in a vertical direction by the actuator 354 to adjust a height of the substrate supporter 340.

The base 360 is provided in a cylindrical shape surrounding the treatment vessel 320 and having an open top. The base 360 includes a bottom 361 and a wall 363. The base 360 is provided in a cup shape. The bottom 361 is provided in a disk shape and may be connected to an exhaust pipe. The wall 363 extends in a vertical direction from the edge of the bottom 361. The base 360 may be made of a resin material having a high acid resistance. The base 360 substantially functions as an outer wall of the entirety of the treatment vessel 320.

The liquid ejector 370 (or a frontside liquid ejector 370) supplies a treatment liquid to the substrate W to process the substrate W. The liquid ejector 370 supplies the treatment liquid to a frontside of the substrate W. For example, an organic solvent such as isopropyl alcohol (IPA) may be ejected from the liquid ejector 370 to dry the frontside of the substrate W.

The airflow supplier 380 forms a downward airflow in the internal space 312 of the housing 310. The airflow supplier 380 includes a fan 382, an airflow supply line 384, and a filter 386. The fan 382 is mounted at an upper side of the housing 310 to form a downward airflow in the internal space 312 of the housing 310. The airflow supply line 384 supplies external air into the housing 310. The filter 386 filters out impurities included in the air.

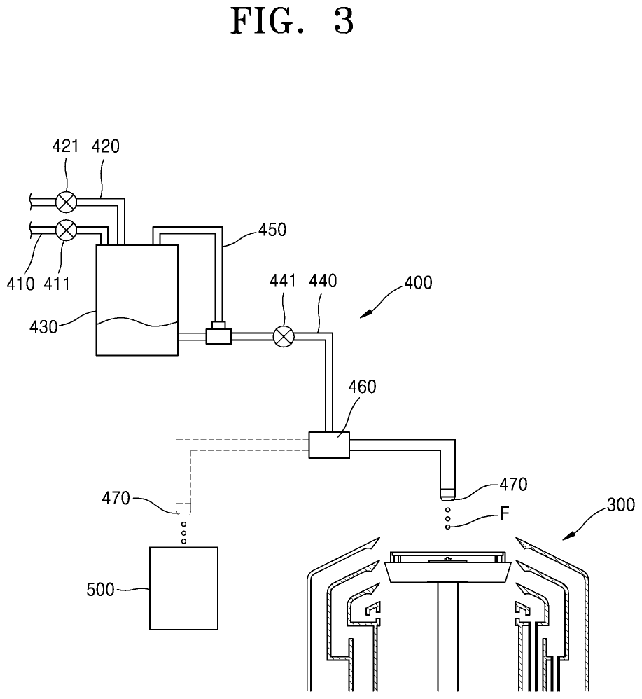

FIG. 3 is a cross-sectional view showing a chemical supply structure according to an embodiment of the present invention.

Referring to FIG. 3, a chemical supply apparatus 400 according to an embodiment of the present invention serves to receive chemicals supplied through a first chemical inlet pipe 410 and a second chemical inlet pipe 420, store the chemicals in a tank 430, and then supply the chemicals to a liquid ejector 470 through a chemical supply pipe 440. The liquid ejector 470 corresponds to the liquid ejector 370 of FIG. 2 and may be provided as a nozzle.

Specifically, the first and second chemical inlet pipes 410 and 420 may be connected to the tank 430 to supply different chemicals to the tank 430. A first inlet valve 411 and a second inlet valve 421 are connected to the first and second chemical inlet pipes 410 and 420, respectively. The first and second inlet valves 411 and 421 may adjust flow rates of the chemicals in the first and second chemical inlet pipes 410 and 420.

The tank 430 is provided to store the received chemicals. The two chemicals received through the first and second chemical inlet pipes 410 and 420 may be mixed in the tank 430. Alternatively, the chemicals may be separately stored in the tank 430.

The chemical stored in the tank 430 may be supplied to the liquid ejector 470 through the chemical supply pipe 440. A chemical supply valve 441 may adjust a flow rate for supplying the chemical. Meanwhile, a circulation pipe 450 may be connected to the chemical supply pipe 440 to circulate the chemical, thereby adjusting a flow rate, a concentration, or the like of the chemical.

A driver 460 may be provided to move the liquid ejector 470. To process the substrate W, the driver 460 may move the liquid ejector 470 to vertically above the substrate W, that is, to above the substrate supporter 340. To test the chemical, the driver 460 may move the liquid ejector 470 toward a chemical tester 500 (or a chemical test apparatus 500). As described below, the liquid ejector 470 may supply the chemical to the chemical tester 500 (or the chemical test apparatus 500) to test the chemical. The chemical tester 500 (or the chemical test apparatus 500) may be included in the substrate processing apparatus 300 or disposed outside the substrate processing apparatus 300.

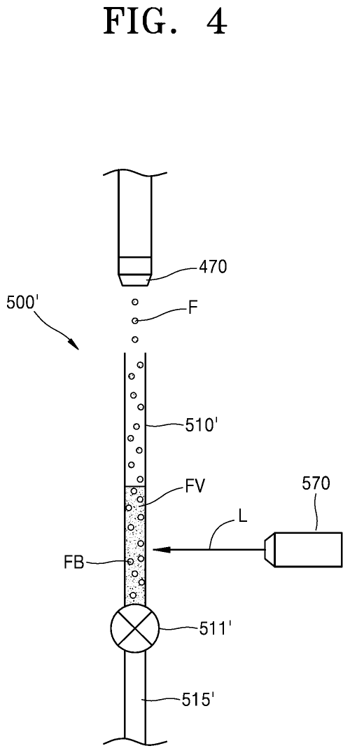

FIG. 4 is a schematic view of an existing chemical test apparatus 500′.

Referring to FIG. 4, the liquid ejector 470 may be positioned above the chemical test apparatus 500′ to test a chemical F. The chemical test apparatus 500′ is provided to test the chemical F by using a photometer 570. The chemical test apparatus 500′ includes an inlet pipe 510′, an outlet pipe 515′, and a valve 511′. The inlet pipe 510′ provides a passage through which the chemical F is introduced, and the outlet pipe 515′ provides a passage through which the chemical F is discharged. The valve 511′ opens or closes a passage between the inlet pipe 510′ and the outlet pipe 515′.

When the valve 511′ is closed and the chemical F is supplied from the liquid ejector 470, the chemical F is filled in the inlet pipe 510′. The photometer 570 may irradiate light L to the filled chemical FV to perform a test such as a contaminant test, a component test, or a concentration test on the filled chemical FV.

However, in the existing chemical test apparatus 500′, a large amount of bubbles FB are formed while the chemical F is being filled in the inlet pipe 510′. Because the inlet pipe 510′ is provided in a vertical direction, the chemical F falls vertically to hit the surface of the filled chemical FV and form numerous bubbles FB. The bubbles FB affect reflection, refraction, scattering, etc. of the light L irradiated from the photometer 570, such that an error occurs in measuring the filled chemical FV.

Therefore, the present invention proposes a chemical test apparatus 500 capable of minimizing the influence of the bubbles FB on a chemical test performed using the photometer 570.

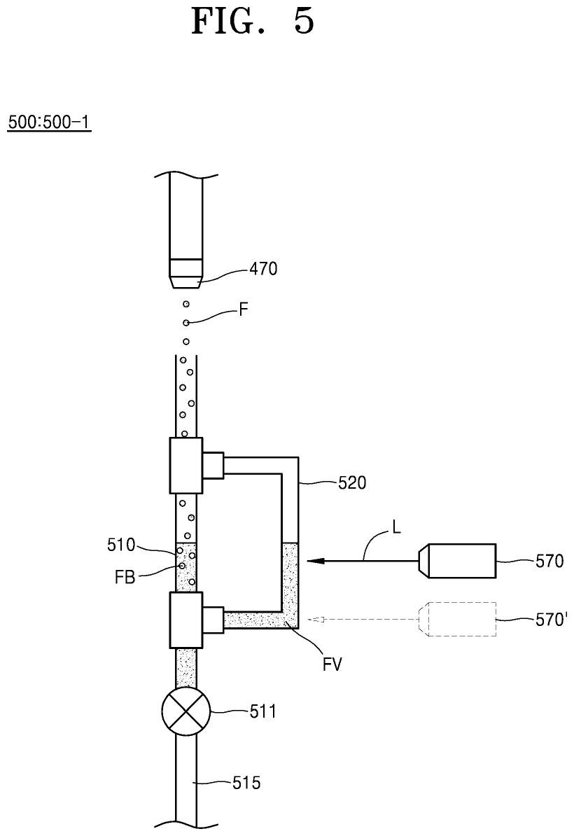

FIG. 5 is a schematic view of a chemical test apparatus 500: 500-1 according to an embodiment of the present invention.

Referring to FIG. 5, the chemical test apparatus 500: 500-1 according to an embodiment of the present invention includes a first line 510, a second line 520, a valve 511, and a discharge line 515. Lines such as the first line 510, the second line 520, and the discharge line 515 may be provided in a pipe shape through which a fluid moves.

The first line 510 may provide an inlet through which the chemical F supplied from the liquid ejector 470 is introduced, and a passage through which the chemical F moves. For example, the first line 510 may be provided to extend in the third direction 16 (or the Z-axis direction). An upper end of the first line 510 may be provided as an inlet. The first line 510 may provide a passage in which the chemical F is filled and through which the chemical F moves. The discharge line 515 may be connected to a lower end of the first line 510.

The valve 511 may be disposed between the first line 510 and the discharge line 515. The valve 511 may open or close a passage between the first line 510 and the discharge line 515.

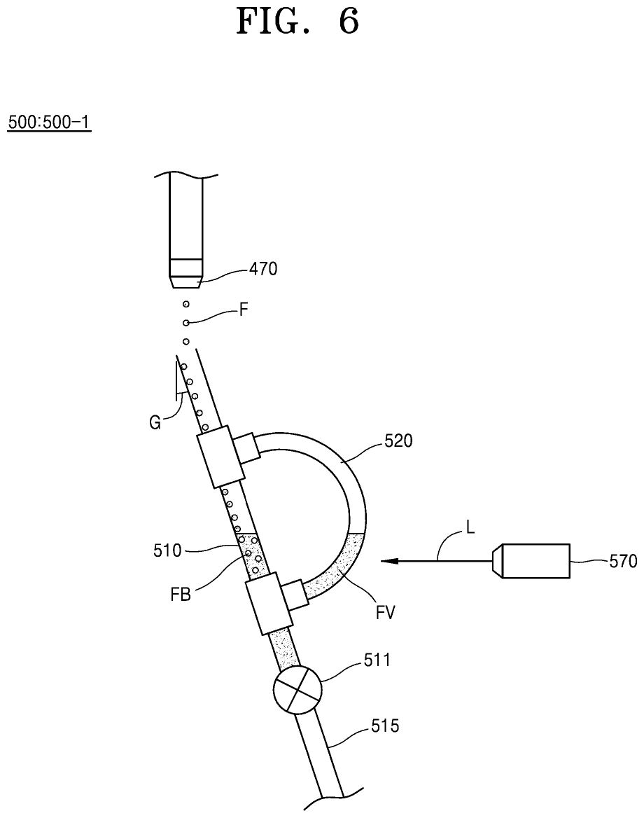

The second line 520 may be connected to two separate points of the first line 510. An end and another end of the second line 520 may be connected to two separate points of the first line 510, which have different heights. For example, the second line 520 may have a ‘[’ shape which is bent twice. As another example, the second line 520 may have an arc shape (see FIG. 6). However, the second line 520 is not limited to a particular shape as long as the second line 520 is connected to two separate points of the first line 510.

The end of the second line 520 may be connected to a lower one of the two separate points of the first line 510, and the other end of the second line 520 may be connected to an upper one of the two separate points of the first line 510. As such, the valve 511 may be disposed at least below the end of the second line 520.

The liquid ejector 470 directly supplies the chemical F to the first line 510 and does not directly supply the chemical F to the second line 520. The chemical F introduced into the first line 510 may move to and be filled in the second line 520. Specifically, when the valve 511 is closed and the liquid ejector 470 supplies the chemical F from above the first line 510, the chemical F is filled from the lower end of the first line 510 and moves through the branched second line 520, i.e., through the end of the second line 520. Thus, the chemical F may be filled from the end to at least a partial passage of the second line 520.

The chemical FV filled in the partial passage of the second line 520 does not directly face the liquid ejector 470 and is not hit by the chemical F which falls vertically. As such, although the bubbles FB are present in the chemical FV filled in the first line 510, less or no bubbles FB may be present in the chemical FV filled in the second line 520. Accordingly, when the photometer 570 irradiates the light L to the filled chemical FV to perform a test, the second line 520 may be used as a target to which the light L is irradiated. That is, the photometer 570 may irradiate the light L to the second line 520 to test the chemical FV.

Passage diameters of the first and second lines 510 and 520 may be the same. Alternatively, to fill the second line 520 with less chemical FV, the passage diameter of the second line 520 may be less than the passage diameter of the first line 510.

Meanwhile, instead of irradicating the light L to a cross-section of the passage of the second line 520, in order to further increase accuracy of measurement, the light L may be irradiated to a region in the second line 520 where more chemical FV is present. In other words, a photometer 570′ (see FIG. 5) may irradiate the light L in a direction parallel to a cross-section of the second line 520, which has a length greater than the passage diameter of the second line 520.

When the test on the filled chemical FV is completed, the valve 511 may be open to discharge the chemical FV in the first and second lines 510 and 520 to the outside through the discharge line 515. Thereafter, when the chemical F is determined to be normal, the driver 460 may move the liquid ejector 470 to above the substrate W of the substrate processing apparatus 300 to process the substrate W.

FIG. 6 is a schematic view of the chemical test apparatus 500: 500-1 according to an embodiment of the present invention when tilted.

The first line 510 does not necessarily extend in the third direction 16 (or the Z-axis direction) and may extend in a direction tilted at a certain angle G with respect to the Z-axis direction. The entirety of the first line 510 may not extend in the direction tilted at the certain angle G with respect to the Z-axis direction and at least a portion of the first line 510 may extend in the direction tilted at the certain angle G with respect to the Z-axis direction.

In this case, when the liquid ejector 470 supplies the chemical F into the inlet of the first line 510, the chemical F may flow along the inner wall of the passage of the first line 510 and be filled in the first line 510. As such, impact with the chemical FV filled in the first line 510 may be reduced and thus the amount of the bubbles FB formed may also be reduced. Because the amount of the bubbles FB in the first line 510 is reduced, the chemical FV with much less bubbles FB may be filled in the passage of the second line 520.

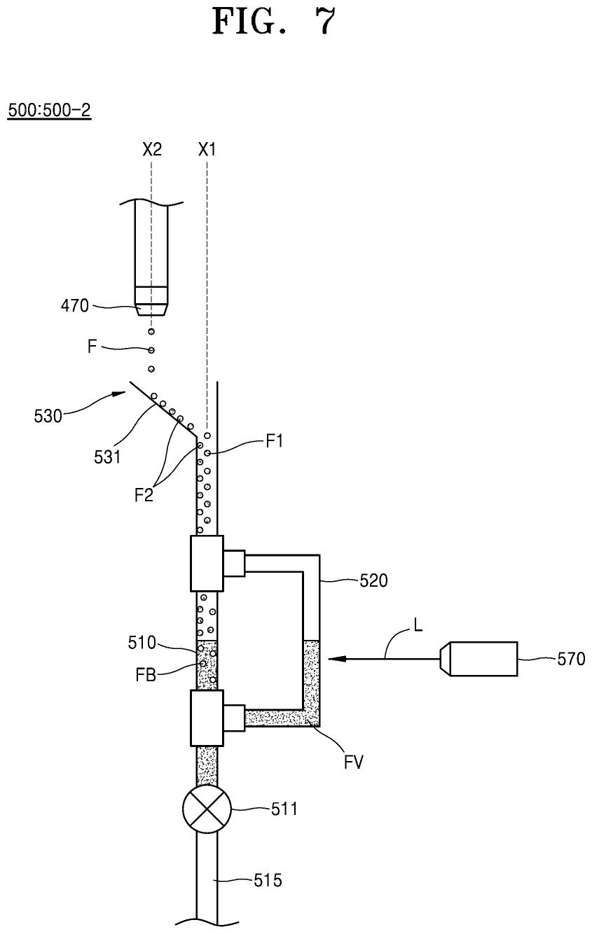

FIG. 7 is a schematic view of a chemical test apparatus 500: 500-2 according to another embodiment of the present invention.

Referring to FIG. 7, the chemical test apparatus 500: 500-2 according to another embodiment may include the first line 510, the second line 520, the valve 511, and the discharge line 515, and further include a drain cup 530 connected to the inlet of the first line 510. The first line 510, the second line 520, the valve 511, and the discharge line 515 are described above in conjunction with FIG. 5, and thus a detailed description thereof is not provided therein.

The drain cup 530 may be provided to have an inner diameter that gradually increases in an upward direction from the inlet of the first line 510. Although the drain cup 530 having a cross-section of a substantially inverted triangle shape is shown in FIG. 7, the drain cup 530 is not limited to a particular shape as long as the inner diameter of the drain cup 530 gradually decreases in a direction from the top to the bottom of the drain cup 530. Alternatively, the drain cup 530 may have an inner diameter equal to or less than that of the inlet of the first line 510. However, the drain cup 530 may provide a receiver 531 along which the chemical F may flow from an axis X2 (or an axis direction X2) different from an axis X1 (or an axis direction X1) along which the first line 510 extends.

Specifically, the receiver 531 of the drain cup 530 may be provided to include the axis direction X2 parallel to and spaced apart from the axis direction X1 along which the first line 510 extends. The receiver 531 may include a plane inclined or curved at a certain angle. Therefore, when the chemical F is supplied onto the plane of the receiver 531, the chemical F may flow down from the axis X2 toward the axis X1 of the first line 510 along the inclined or curved plane. The chemical F2 flowing along the receiver 531 may flow down along the inner wall of the passage of the first line 510 and be filled in the first line 510. Although some chemical F1 may not flow along the inner wall of the passage of the first line 510 and hit the surface of the chemical FV filled in the first line 510, an amount thereof may be much less than the amount of the chemical F2. As such, the amount of the bubbles FB in the first line 510 may be reduced and the chemical FV with much less bubbles FB may be filled in the passage of the second line 520.

Meanwhile, in the chemical test apparatus 500: 500-2 of FIG. 7, the first line 510 may be tilted at the certain angle G with respect to the third direction 16 (or the Z-axis direction) as shown in FIG. 6. Then, the chemical F may primarily flow along the plane of the receiver 531 of the drain cup 530 and secondarily flow along the inner wall of the first line 510, and thus the amount of the bubbles FB may be further reduced.

In addition, the drain cup 530 may prevent scattering of the chemical F to prevent the liquid ejector 470, components near the liquid ejector 470, components outside the chemical test apparatus 500 in FIG. 3, etc. from being contaminated with the chemical F. Furthermore, when the chemical F is scattered and then the scattered chemical F is introduced into the first line 510, the drain cup 530 may reduce contamination of the scattered chemical F.

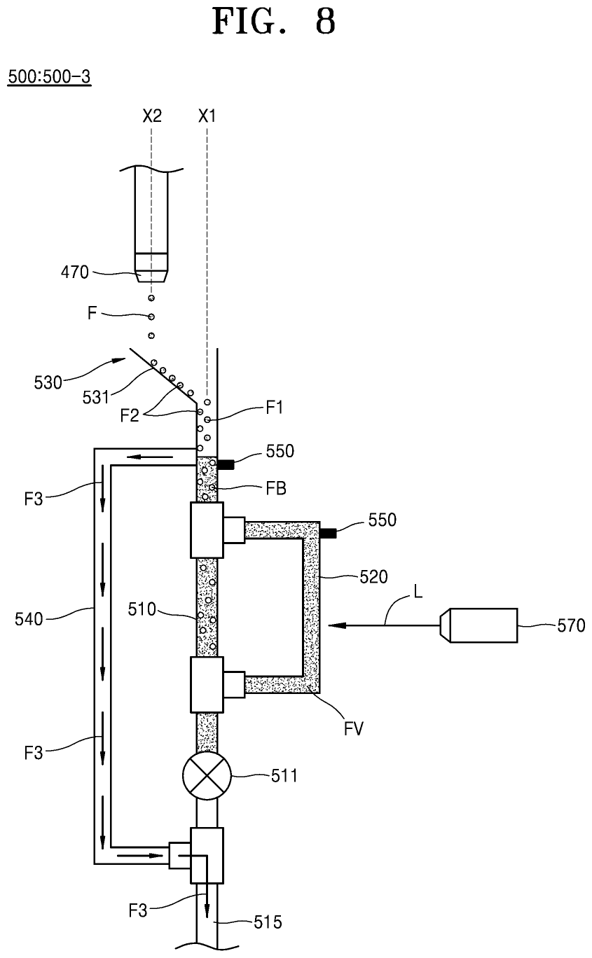

FIG. 8 is a schematic view of a chemical test apparatus 500: 500-3 according to another embodiment of the present invention.

Referring to FIG. 8, the chemical test apparatus 500: 500-3 according to another embodiment may include the first line 510, the second line 520, the valve 511, the discharge line 515, and the drain cup 530, and further include a third line 540. The first line 510, the second line 520, the valve 511, the discharge line 515, and the drain cup 530 are described above in conjunction with FIGS. 5 and 6, and thus a detailed description thereof is not provided therein.

The third line 540 may be connected to two separate points respectively included in the first line 510 and the discharge line 515. An end of the third line 540 may be connected to a point of the discharge line 515 below the valve 511, and another end of the third line 540 may be connected to a point of the first line 510 above the other end of the second line 520. That is, the end of the third line 540 may be positioned below the valve 511, and the other end of the third line 540 may be positioned above the second line 520.

When the chemical F is supplied while the valve 511 is closed, the chemical F is filled in the first and second lines 510 and 520. In this state, when the chemical F is continuously supplied, the chemical F may be filled up to the inlet of the first line 510 and overflowed. Alternatively, when a level of the filled chemical FV is high, the liquid ejector 470 may be close to the surface of the filled chemical FV and thus a possibility of forming the bubbles FB is increased.

As such, the third line 540 is provided to discharge the exceeding chemical F3 through the discharge line 515 after the chemical F required for a chemical test is filled in at least the second line 520. When the chemical F is fully filled in the first and second lines 510 and 520 and further filled to the other end of the third line 540, the chemical F3 may move along a passage of the third line 540 and be discharged through the discharge line 515.

Meanwhile, according to an embodiment, a sensor 550 may be disposed on the second line 520 and/or on a point of the first line 510 above the other end of the second line 520. The sensor 550 is provided to detect whether the chemical F is filled. As such, before the chemical F3 is discharged through the third line 540, the sensor 550 may detect that the chemical F is filled, to stop the liquid ejector 470 from supplying the chemical F.

According to the afore-described embodiments of the present invention, convenience and reliability a chemical test may be increased by performing the chemical test on a chemical without bubbles.

In addition, according to the embodiments of the present invention, accuracy of measurement may be increased by preventing contamination of a chemical.

However, the scope of the present invention is not limited to the above effects.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A chemical test apparatus for testing a chemical used to process a substrate, the chemical test apparatus comprising:
a first line providing an inlet through which the chemical is introduced, and a passage through which the chemical moves;
a second line having an end and another end connected to two separate points of the first line, and providing a passage in which the chemical introduced into the first line is filled;
a discharge line connected to a lower end of the first line; and
a valve disposed between the first line and the discharge line at least below portions of the first line connected to the second line, to open or close a passage through which the chemical moves from the first line to the discharge line.

2. The chemical test apparatus of claim 1, wherein the end of the second line is connected to a lower one of the two separate points of the first line, and the other end of the second line is connected to an upper one of the two separate points of the first line.

3. The chemical test apparatus of claim 2, wherein a photometer irradiates light to the chemical to perform a test, and the second line is provided as a target to which the light is irradiated.

4. The chemical test apparatus of claim 3, wherein, when the valve is closed, the chemical introduced into the first line is filled from the lower end of the first line and filled in at least a partial passage of the second line.

5. The chemical test apparatus of claim 4, wherein the chemical filled in the second line comprises less bubbles than the chemical filled in the first line, and is provided as a target to which the light is irradiated.

6. The chemical test apparatus of claim 1, wherein the first line extends in a Z-axis direction.

7. The chemical test apparatus of claim 1, wherein the first line extends in a direction tilted at a certain angle with respect to a Z-axis direction.

8. The chemical test apparatus of claim 1, wherein a passage diameter of the second line is less than or equal to a passage diameter of the first line.

9. The chemical test apparatus of claim 2, wherein a direction parallel to a cross-section of the second line, which has a length greater than a passage diameter of the second line, is provided as a direction in which a light is irradiated.

10. The chemical test apparatus of claim 1, wherein a drain cup is connected to the inlet of the first line and provides a receiver comprising an axis direction parallel to and spaced apart from at least an axis direction along which the first line extends.

11. The chemical test apparatus of claim 10, wherein the receiver comprises a plane inclined or curved at a certain angle, and
wherein the chemical is supplied onto the plane of the receiver.

12. The chemical test apparatus of claim 2, further comprising a third line having an end and another end connected to two separate points respectively included in the first line and the discharge line, and providing a passage through which the chemical moves,
wherein the end of the third line is connected to a point of the discharge line below the valve, and the other end of the third line is connected to a point of the first line above the other end of the second line.

13. The chemical test apparatus of claim 12, wherein, when the chemical is fully filled in the second line, the chemical moves along the passage of the third line and is discharged through the discharge line.

14. The chemical test apparatus of claim 2, wherein a sensor for detecting whether the chemical is filled is provided on the second line and/or on a point of the first line above the other end of the second line.

15. A substrate processing apparatus comprising:
a substrate supporter provided to support a substrate;
a liquid ejector for ejecting a chemical used to process the substrate; and
a chemical tester for testing the chemical used to process the substrate,
wherein the chemical tester comprises:
a first line providing an inlet through which the chemical is introduced, and a passage through which the chemical moves;
a second line having an end and another end connected to two separate points of the first line, and providing a passage in which the chemical introduced into the first line is filled;
a discharge line connected to a lower end of the first line; and
a valve disposed between the first line and the discharge line at least below portions of the first line connected to the second line, to open or close a passage through which the chemical moves from the first line to the discharge line.

16. The substrate processing apparatus of claim 15, further comprising a driver for moving the liquid ejector toward the chemical tester or the substrate supporter.

17. The substrate processing apparatus of claim 15, further comprising a photometer for irradiating light to the second line of the chemical tester to test the chemical filled in the second line.

18. The substrate processing apparatus of claim 16, wherein a drain cup is connected to the inlet of the first line and provides a receiver comprising an axis direction parallel to and spaced apart from at least an axis direction along which the first line extends,
wherein the receiver comprises a plane inclined or curved at a certain angle, and
wherein the driver moves the liquid ejector to a position vertically spaced apart from the receiver, to supply the chemical onto the plane of the receiver.

19. The substrate processing apparatus of claim 15, wherein the chemical tester further comprises a third line having an end and another end connected to two separate points respectively included in the first line and the discharge line, and providing a passage through which the chemical moves,
wherein the end of the third line is connected to a point of the discharge line below the valve, and the other end of the third line is connected to a point of the first line above the other end of the second line, and
wherein, when the chemical is fully filled in the second line, the chemical moves along the passage of the third line and is discharged through the discharge line.

20. A chemical test apparatus for testing a chemical used to process a substrate, the chemical test apparatus comprising:
a first line providing an inlet through which the chemical is introduced, and a passage through which the chemical moves;
a second line having an end and another end connected to two separate points of the first line, and providing a passage in which the chemical introduced into the first line is filled;
a discharge line connected to a lower end of the first line;
a third line having an end and another end connected to two separate points respectively included in the first line and the discharge line, and providing a passage through which the chemical moves; and
a valve disposed between the first line and the discharge line at least below portions of the first line connected to the second line, to open or close a passage through which the chemical moves from the first line to the discharge line,
wherein the end of the second line is connected to a lower one of the two separate points of the first line, and the other end of the second line is connected to an upper one of the two separate points of the first line,
wherein the end of the third line is connected to a point of the discharge line below the valve, and the other end of the third line is connected to a point of the first line above the other end of the second line,
wherein a drain cup is connected to the inlet of the first line and provides a receiver comprising an axis direction parallel to and spaced apart from at least an axis direction along which the first line extends,
wherein the receiver comprises a plane inclined or curved at a certain angle,
wherein the chemical is supplied onto the plane of the receiver to flow along the plane of the receiver toward the inlet of the first line,
wherein, when the valve is closed, the chemical introduced into the first line is filled from the lower end of the first line and filled in at least a partial passage of the second line, and
wherein a photometer irradiates light to the chemical to perform a test, and the second line is provided as a target to which the light is irradiated.
